(19) United States
(12) Patent Application Publication
(10) Pub. No.: US 2009/0140361 A1
(43) Pub. Date: Jun. 4, 2009

(54) Image Sensor and Method of Manufacturing the Same

(76) Inventor: Seong Hun Jeong, Nowon-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/267,726

(22) Filed: Nov. 10, 2008

(30) Foreign Application Priority Data
Nov. 30, 2007 (KR) 10-2007-0123567

(51) Int. Cl. H01L 31/00; H01L 21/00

(52) U.S. Cl. 257/432; 438/69; 257/E31.001

(57) ABSTRACT

An image sensor and manufacturing method thereof are provided. The image sensor can includes a semiconductor substrate including a light receiving element, a metal interconnection layer having a trench, a guide pattern on a sidewall of the trench, and a color filter in the trench. Since the color filter can be formed in the trench, a length of a light path can be reduced, thereby improving the performance of the image sensor.

### CROSS-REFERENCE TO RELATED APPLICATION

The present application claims the benefit under 35 U.S.C. §119 of Korean Patent Application No. 10-2007-0123567, filed Nov. 30, 2007, which is hereby incorporated by reference in its entirety.

### BACKGROUND

In general, an image sensor is a semiconductor device that converts an optical image into an electrical signal. The image sensor is typically classified as a charge coupled device (CCD) image sensor or a complementary metal oxide semiconductor (CMOS) image sensor (CIS).

A unit pixel of such a CIS includes a photodiode and a metal oxide semiconductor (MOS) transistor. In operation, the CIS sequentially detects an electrical signal of the unit pixel in a switching manner to generate an image.

### BRIEF SUMMARY

Embodiments of the present invention provide an image sensor and manufacturing method thereof, capable of enhancing optical characteristics of the sensor to improve photo sensitivity.

In an embodiment, an image sensor can comprise: a semiconductor substrate comprising a first light receiving element; a metal interconnection layer on the semiconductor substrate, wherein the metal interconnection layer comprises a first trench; a guide pattern disposed on a sidewall of the first trench; and a first color filter in the first trench.

In another embodiment, a method of manufacturing an image sensor can comprise: forming a metal interconnection layer on a semiconductor substrate comprising a first light receiving element; forming a first trench in the metal interconnection layer; forming a guide pattern on a sidewall of the first trench; and forming a first color filter in the first trench.

Embodiments of the present invention are capable of utilizing light incident onto the image sensor with minimal to no light loss, while inhibiting adjacent pixels from interfering with each other.

According to embodiments, a color filter can be formed in a trench to reduce the length of a light path, thereby improving performance of the image sensor.

### BRIEF DESCRIPTION OF THE DRAWINGS

FIGS. 1 to 7 are cross-sectional views showing a method of manufacturing an image sensor according to an embodiment of the present invention.

### DETAILED DESCRIPTION

Hereinafter, an image sensor and a method of manufacturing the same according to embodiments of the present invention will be described in detail with reference to accompanying drawings.

It should be noted that the size (dimension) of elements shown in the drawings may be magnified for the purpose of clear explanation and the real size of the elements may be different from the size of elements shown in drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

Although the present disclosure includes reference to drawings showing a complimentary metal oxide semiconductor image sensor (CIS), embodiments of the present invention are not limited thereto. A skilled artisan will recognize that the present invention is applicable for various image sensors, including a charge-coupled device (CCD) image sensor.

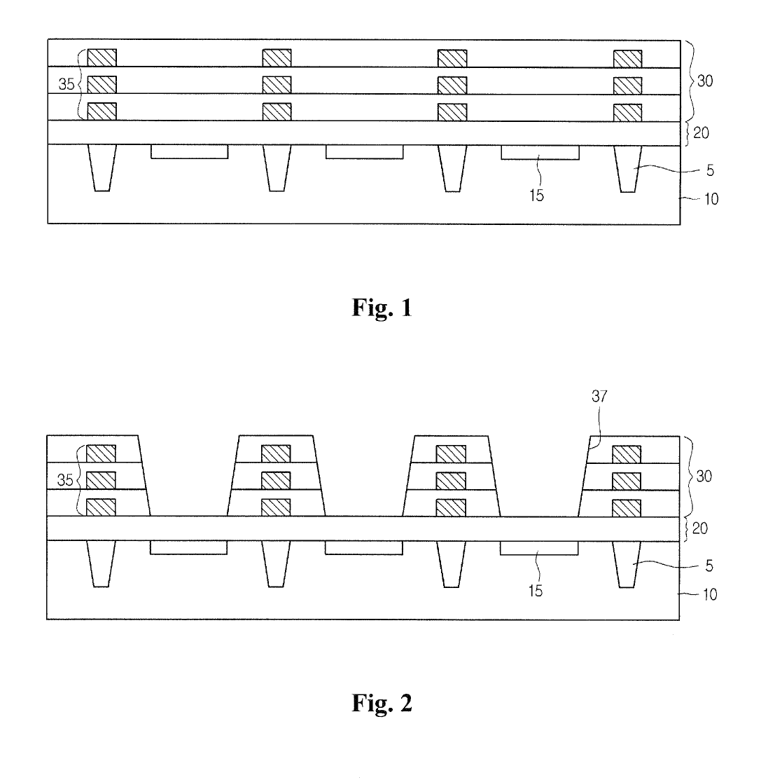

FIGS. 1 to 7 are cross-sectional views showing a method of manufacturing an image sensor according to an embodiment of the present invention.

Referring to FIG. 1, an isolation layer 5 and a light receiving element 15 can be formed on a semiconductor substrate 10. The light receiving element can be, for example, a photodiode.

A circuit layer 20 can be formed on the semiconductor substrate 10 including the isolation layer 5 and the light receiving element 15. The circuit layer 20 can include any suitable circuit elements known in the art, for example, a transistor.

A metal interconnection layer 30 can be formed on the circuit layer 20. The metal interconnection layer 30 can include an interconnection 35. The interconnection 35 can be electrically connected to the circuit layer 20.

Referring to FIG. 2, a trench 37 can be formed in the metal interconnection layer 30. The trench 37 can be formed such that a portion of the circuit layer 20 is exposed.

The trench 37 can be formed by any suitable method known in the art. For example, the trench 37 can be formed by forming a photoresist pattern on the metal interconnection layer 30 and then etching the photoresist pattern.

In an embodiment, the trench 37 can be formed such that at least a portion of the trench 37 is over the light receiving element 15.

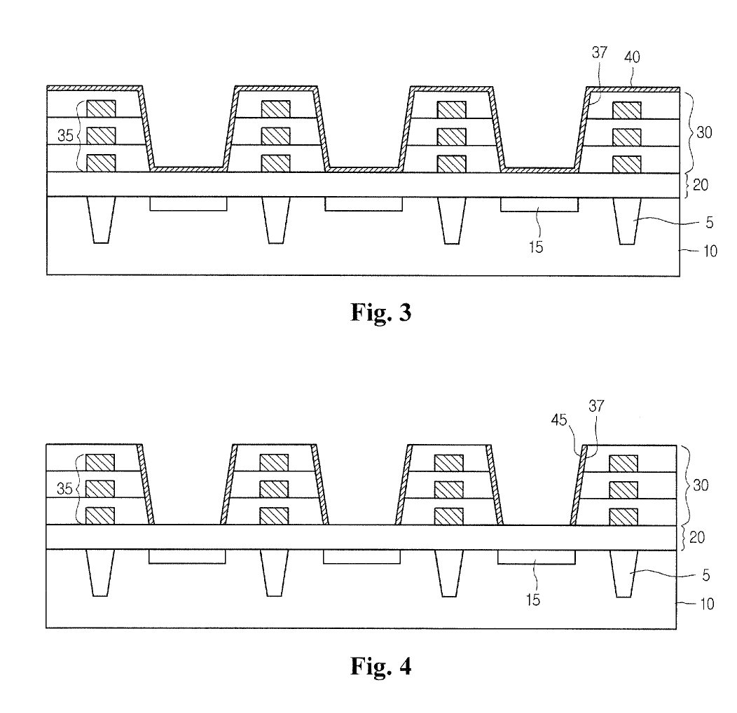

Referring to FIG. 3, a guide layer 40 can be formed on the metal interconnection layer 30 including the trench 37. That is, the guide layer 40 can be formed on the metal interconnection layer 30 and in the trench 37.

In an embodiment, the guide layer 40 can include a metal layer. The metal layer can be any suitable material known in the art, for example, Al, Cu, tantalum (Ta), titanium (Ti), W, gold (Au), silver (Ag), Al-based metal, or any combination thereof.

The guide layer 40 can reflect incident light such that the light can remain in a pixel, thereby minimizing light loss.

Referring to FIG. 4, a guide pattern 45 can be formed at a sidewall of the trench 37. In an embodiment, the guide pattern 45 can be formed by performing an etch process to the guide layer 40 with respect to the semiconductor substrate 10 including the trench 37 and the metal interconnection layer 30. In a specific embodiment, the etch process can be a plasma blanket etch process. A plasma blanket etch process is an anisotropic etching process having a high degree of directivity.

That is, a portion of the guide layer 40 on a bottom surface of the trench 37 and an upper surface of the metal interconnection layer 30, can be removed through the plasma blanket etch process, thereby forming the guide pattern 45 on the sidewall of the trench 37.

Since a portion of the guide layer 40 on the bottom surface of the trench 37 can be removed, light transmittance properties of the image sensor can be improved since the amount of light incident onto the light receiving element 15 can be increased.

In addition, when light is incident toward the metal interconnection 35, the guide pattern 45 formed on the sidewall of the trench 37 can help block the light so that it is not incident into the metal interconnection layer 30. Thus, cross talk and noise can be inhibited from occurring in the image sensor.

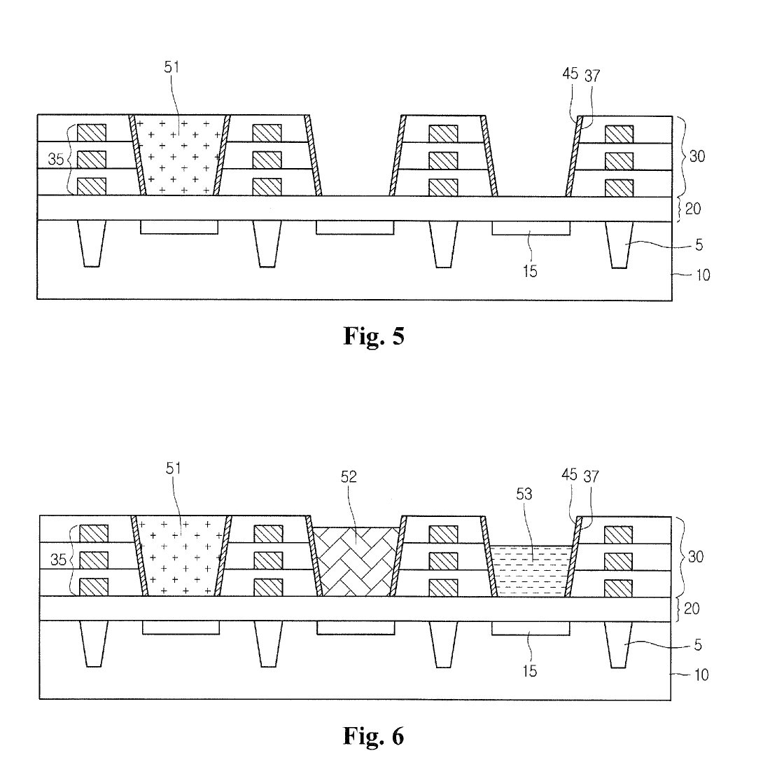

Then, referring to FIG. 5, a first photoresist color filter 51 can be formed on the circuit layer 20 such that the first photoresist color filter 51 is in at least one trench 37.

In an embodiment, the first photoresist color filter 51 can be formed by exposing a first photoresist color filter layer using a pattern mask and then developing the first photoresist color filter layer.

Referring to FIG. 6, a second photoresist color filter 52 can be formed in at least one trench 37 in which the first photoresist color filter 51 is not formed.

In an embodiment, the second photoresist filter 52 can be formed by exposing a second photoresist color filter layer using a pattern mask and then developing the second photoresist color filter layer.

Additionally, a third photoresist color filter 53 can be formed in at least one trench 37 in which neither the first photoresist color filter 51 nor the second photoresist color filter 52 is formed.

In an embodiment, the third photoresist color filter 53 can be formed by exposing a third photoresist color filter layer using a pattern mask and then developing the third photoresist color filter layer.

Each of the first to third photoresist color filters 51, 52, and 53 can be a red color filter, a green color filter, or a blue color filter. In an embodiment, the first photoresist color filter 51 is a red color filter, the second photoresist color filter 52 is a green color filter, and the third photoresist color filter 53 is a blue color filter

As described above, photoresist color filter material can be filled in each trench 37 formed on the semiconductor substrate 10, so that a color filter array can be formed corresponding to each unit pixel.

In an embodiment, the first photoresist color filter 51 can have a thickness that is different than a thickness of the second photoresist color filter 52 and a thickness of the third photoresist color filter 53. Also, the thickness of the second photoresist color filter 52 can be different than the thickness of the third photoresist color filter 53. That is, each of the first to third photoresist color filters 51, 52, and 53 can have a thickness different from each other. In addition, the height of the upper surface of the filters can decrease in the sequence of a red color filter, a green color filter, and a blue color filter, such that a red color filter has the largest thickness and the blue color filter has the smallest thickness. This is because the first to third photoresist color filters 51, 52, and 53 can filter light having different wavelengths according to the color of each color filter.

According to embodiments of the present invention, since a color filter can be formed in the trench 37, a length of a light path can be reduced, thereby improving performance of the image sensor.

In addition, when light is incident toward the metal interconnection 35, the guide pattern 45 formed on the sidewall of the trench 37 can help block the light from passing through the metal interconnection layer 30, so that cross talk and noise can be inhibited, thereby improving the image quality of the image sensor.

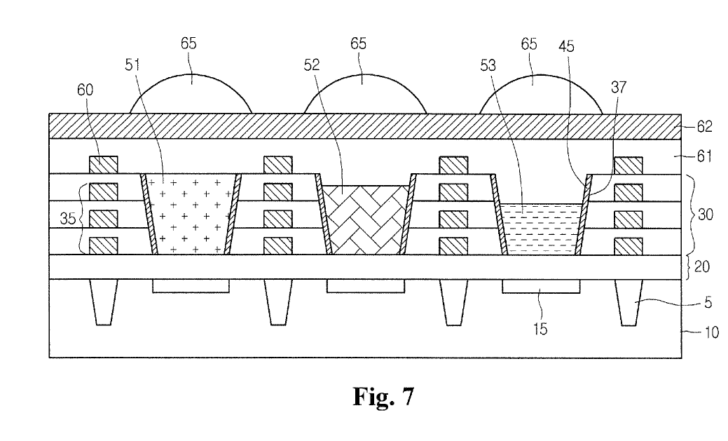

Referring to FIG. 7, in an embodiment, a first protective layer 61 can be formed on the semiconductor substrate 10 having the color filter array formed in the trenches 37. 1 n one embodiment, a second protective layer 62 can be formed on the first protective layer 62.

The first protective layer 61 can serve to planarize a step difference of the color filters that may have differing heights.

In a further embodiment, a microlens 65 can be formed on the second protective layer 62. A microlens 65 can be formed over each of the first to third photoresist color filters 51, 52, and 53.

In yet a further embodiment, a pad 60 can be formed on the metal interconnection layer 30 before forming the first protective layer 61. The pad 60 can be formed over the metal interconnection 35.

According to embodiments of the present invention, light loss caused by light refraction can be minimized due to the guide pattern 45 formed along an inner wall of the trench 37.

In addition, when light is incident toward the metal interconnection 35, the guide pattern 45 formed at the sidewall of the trench 37 can help block the light from passing through the metal interconnection layer 30, so that cross talk and noise can be inhibited. Accordingly, the image quality of the image sensor can be improved.

Moreover, according to embodiments, since a color filter array can be formed in the trench 37, an additional color filter array is not necessary. Accordingly, a length of a light path can be reduced, thereby inhibiting light loss and increasing the light efficiency of the image sensor.

Furthermore, according to embodiments, a color filter array layer can be omitted, leading to a reduced thickness of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a semiconductor substrate comprising a first light receiving element;
a metal interconnection layer on the semiconductor substrate, wherein the metal interconnection layer comprises a first trench;
a guide pattern disposed on a sidewall of the first trench; and
a first color filter in the first trench.

2. The image sensor according to claim 1, wherein at least a portion of the first trench is disposed over the first light receiving element.

3. The image sensor according to claim 1, wherein at least a portion of the first color filter is disposed over the first light receiving element.

4. The image sensor according to claim 1, further comprising a microlens disposed over the first color filter.

5. The image sensor according to claim 1, wherein the guide pattern comprises a metallic material.

6. The image sensor according to claim 1, wherein the metal interconnection layer further comprises a second trench and a third trench, and wherein the guide pattern is disposed on a sidewall of the second trench and a sidewall of the third trench.

7. The image sensor according to claim 6, further comprising:
a second color filter in the second trench; and
a third color filter in the third trench.

8. The image sensor according to claim 7, wherein the semiconductor substrate further comprises a second light receiving element and a third light receiving element; wherein at least a portion of the first trench is over the first light receiving element, and wherein at least a portion of the second trench is over the second light receiving element, and wherein at least a portion of the third trench is over the third light receiving element.

9. The image sensor according to claim 7, wherein a thickness of the first color filter is different than a thickness of the second color filter and a thickness of the third color filter, and wherein the thickness of the second color filter is different than the thickness of the third color filter.

10. The image sensor according to claim 7, further comprising a planarization layer on the metal interconnection layer and the first, second, and third color filters, filling at least a portion of the third trench.

11. A method of manufacturing an image sensor, comprising:
forming a metal interconnection layer on a semiconductor substrate comprising a first light receiving element;
forming a first trench in the metal interconnection layer;
forming a guide pattern on a sidewall of the first trench; and
forming a first color filter in the first trench.

12. The method according to claim 11, wherein forming the guide pattern on a sidewall of the trench comprises:
forming a metal layer on the metal interconnection layer including the first trench; and
performing a plasma blanket etch process to etch a portion of the metal layer at a bottom of the first trench and on a top surface of the metal interconnection layer.

13. The method according to claim 11, wherein at least a portion of the first trench is formed over the first light receiving element.

14. The method according to claim 11, further comprising forming a microlens over the first color filter.

15. The method according to claim 11, further comprising:
forming a second trench and a third trench in the metal interconnection layer at the same time as the first trench is formed; and
forming the guide pattern on a sidewall of the second trench and a sidewall of the third trench.

16. The method according to claim 15, further comprising:
forming a second color filter in the second trench; and
forming a third color filter in the third trench.

17. The method according to claim 16, wherein the semiconductor substrate further comprises a second light receiving element and a third light receiving element; wherein at least a portion of the first trench is formed over the first light receiving element, and wherein at least a portion of the second trench is formed over the second light receiving element, and wherein at least a portion of the third trench is formed over the third light receiving element.

18. The method according to claim 16, wherein a thickness of the first color filter is different than a thickness of the second color filter and a thickness of the third color filter, and wherein the thickness of the second color filter is different than the thickness of the third color filter.

19. The method according to claim 16, further comprising forming a planarization layer on the metal interconnection layer and the first, second, and third color filters, filling at least a portion of the third trench.

20. The method according to claim 11, wherein the guide pattern comprises a metallic material.
